(19) United States
(12) Patent Application Publication
(10) Pub. No.: US 2007/0229139 A1
(43) Pub. Date: Oct. 4, 2007

(54) LEVEL SHIFTER CIRCUIT WITH A WIDE OPERATING VOLTAGE RANGE

(76) Inventor: Chun-Hung Lin, Hsinchu City (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(21) Appl. No.: 11/308,491

(22) Filed: Mar. 30, 2006

(51) Int. Cl. H03L 5/00

(52) U.S. Cl. 327/333

(57) ABSTRACT

A level shifter circuit with a wide operating voltage range includes an inverter, a first transistor, a second transistor, a third transistor, a fourth transistor, a fifth transistor and a sixth transistor, wherein electrical characteristics of the third transistor and the sixth transistor are opposite to those of the first transistor, the second transistor, the fourth transistor and the fifth transistor, and the second transistor and the fifth transistor have low threshold voltages and high breakdown voltage terminal. The input terminal of the inverter receives the input signal and is electrically coupled to the gates of the fourth transistor and the fifth transistor, while the output terminal thereof is electrically coupled to the gates of the first transistor and the second transistor.

### BACKGROUND OF THE INVENTION

1. Field of Invention

The present invention relates to a level shifter circuit, and more particularly, to a level shifter circuit with a wide operating voltage range.

2. Description of the Related Art

With advance of the science and technology, new electronic products pursue the advantages of light weight, thin, short and compactness along with providing more functionalities. Therefore, a power voltage used in an internal circuit of current electronic products terminals to be lowered and the number and varieties of employed circuits or integrated circuit chips (IC chips) are aggressively demanded. To be adapted for the preceding tendency, a variety of voltage levels is demanded to provide the circuits or IC chips, and to achieve the goal, a level shifter circuit is indispensable and plays a major role.

FIG. 1 is a schematic drawing of a conventional level shifter circuit. Referring to FIG. 1, the level shifter circuit includes an inverter 102, N-type transistors 104 and 110, and P-type transistors 108 and 114. An input terminal of the inverter 102 is electrically coupled to an operating voltage VL, another input terminal is electrically coupled to an input signal IN and to the gate of the transistor 110, and the output terminal of the inverter 102 is electrically coupled to the gate of the transistor 104. One source/drain of the transistor 104 is electrically coupled to one source/drain of the transistor 108 and to the gate of the transistor 114, while another source/drain of the transistor 104 is electrically coupled to the ground GND. Another source/drain of the transistor 108 is electrically coupled to a power supply VCC and to one source/drain of the transistor 114. Another source/drain of the transistor 114 is electrically coupled to the gate of the transistor 108 and to one source/drain of the transistor 110, and from the node connected between the transistor 114 and the transistor 110, there provides an output signal “OUT.” Another source/drain of the transistor 110 is electrically coupled to the grounding terminal GND.

In general, threshold voltages of the transistors 104 and 110 in a conventional circuit is between 0.7V˜0.8V. Thus, if the operating voltage VL of the inverter 102 is less than 1V, for example in a range between 0.7V˜0.8V, even lower than 0.7V˜0.8V, the N-type transistor 104 or 110 cannot be driven, which causes the malfunction of the conventional level shifter circuit.

To improve a slow-response problem from the signal input to the signal output of the circuit shown in FIG. 1, another conventional circuit as shown in FIG. 2 was developed. FIG. 2 is a schematic drawing of a conventional level shifter circuit. Referring to FIG. 2, the level shifter circuit includes an inverter 202, N-type transistors 204 and 210, and P-type transistors 206, 208, 212 and 214. Wherein, the reference numerals 202, 204, 208, 210 and 214 correspond to their counterparts 102, 104, 108, 110 and 114 in FIG. 1, and their coupling configurations shown in Fog.2 are similar to those shown in FIG. 1, so their description are not repeatedly. Compared with FIG. 1, in FIG. 2 an additional P-type transistor 206 is connected in series between the transistor 204 and the transistor 208 and an additional P-type transistor 212 is connected in series between the transistor 210 and the transistor 214. One source/drain of the transistor 206 is electrically coupled to one source/drain of the transistor 208, another source/drain thereof is electrically coupled to one source/drain of the transistor 204, and the gate thereof is electrically coupled to the gate of the transistor 204. One source/drain of the transistor 212 is electrically coupled to one source/drain of the transistor 214, another source/drain thereof is electrically coupled to one source/drain of the transistor 210, and the gate thereof is electrically coupled to the gate of the transistor 210.

Compared with the circuit of FIG. 1, the circuit of FIG. 2 has an advantage of a quick response between the signal input and the signal output. However, a threshold voltage of the employed transistors is still between 0.7V˜0.8V. Hence if the operating voltage VL of the inverter 202 is less than 1V, the output of the inverter may not be sufficient to drive the transistors 204 and 206 or 210 and 212, which also causes the malfunction of the conventional level shifter circuit.

### SUMMARY OF THE INVENTION

An object of the present invention is to provide a level shifter circuit with wide operating voltage range, mainly suitable for improving the problem of how to prevent the malfunction of the level shifter circuit when the operating voltage of the inverter is less than 1V and the output of the inverter consequently does not attain the required threshold voltage of the transistors.

To obtain the above-described or other objects, the present invention provides a level shifter circuit with wide operating voltage range, which includes an inverter, a first transistor, a second transistor, a third transistor, a fourth transistor, a fifth transistor and a sixth transistor. Wherein, electrical characteristics of the third transistor and the sixth transistor is opposite to that of a first transistor, a second transistor, a fourth transistor and a fifth transistor; the second transistor and the fifth transistor have low threshold voltages and high breakdown voltages, while the first transistor and the fourth transistor have low threshold voltage.

An input terminal of the inverter receives an operating voltage VL, another input terminal thereof receives an input signal IN and is electrically coupled to the gate of the fourth transistor and the gate of the fifth transistor, while the output terminal of the inverter is electrically coupled to the gate of the first transistor and the gate of the second transistor. One source/drain of the second transistor is electrically coupled to one source/drain of the third transistor and the gate of the sixth transistor, at the node connected between the second transistor and the third transistor, there outputs an inverted output signal/OUT, and another source/drain of the second transistor is electrically coupled to one source/drain of the first transistor. Another source/drain of the first transistor is electrically coupled to the ground GND. Another source/drain of the third transistor is electrically coupled to a power supply VCC and one source/drain of the sixth transistor. The gate of the sixth transistor is electrically coupled to the node connected between the second transistor and the third transistor, another source/drain of the sixth transistor is electrically coupled to the gate of the third transistor and one source/drain of the fifth transistor, and from the node connected between the fifth transistor and the sixth transistor, there outputs an output signal OUT. Another source/drain of the fifth transistor is electrically coupled to one source/drain of the fourth transistor. Another source/drain of the fourth transistor is electrically coupled to the ground GND.

The present invention employs transistors with low threshold voltage and high breakdown voltage for the second transistor and the fifth transistor as a design change, and further employs transistors with low threshold voltage for the first transistor and the fourth transistor, thus, even the operating voltage of the inverter is less than 1V, the output of the inverter is able to attain the required threshold voltage of the transistors, which permits the level shifter circuit to normally work.

To achieve the above-described or other objects, the present invention further provides a level shifter circuit with wide operating voltage range, which includes an inverter, a first transistor, a second transistor, a third transistor and a fourth transistor. Wherein, the second transistor and the fourth transistor are doped with a first type impurity while the first transistor and the third transistor are doped with a second type impurity.

An input terminal of the inverter receives an operating voltage VL, while another input terminal thereof receives an input signal IN and is electrically coupled to the gate of the third transistor. One source/drain of the first transistor is electrically coupled to the ground, while the gate thereof receives the output from the inverter. One source/drain of the second transistor is electrically coupled to another source/drain of the first transistor, and from the node connected between the first transistor and the second transistor, there outputs an inverted output signal/OUT. Another source/drain of the second transistor is electrically coupled to a power supply. One source/drain of the third transistor is electrically coupled to the ground, while the gate thereof receives the input signal. One source/drain of the fourth transistor and the gate thereof are electrically coupled to another source/drain of the third transistor and another source/drain of the first transistor, respectively, and from the node connected between the third transistor and the fourth transistor, there outputs an output signal OUT. Another source/drain of the fourth transistor is electrically coupled to the power supply.

The present invention employs transistors with low threshold voltages and high breakdown voltages for the first transistor and the third transistor as a design change, thus, even the operating voltage of the inverter is less than 1V, the output of the inverter is able to achieve the required threshold voltage of the transistors, which enables the level shifter circuit to normally work.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve for explaining the principles of the invention.

FIG. 1 and 2 are schematic drawings of conventional level shifter circuits.

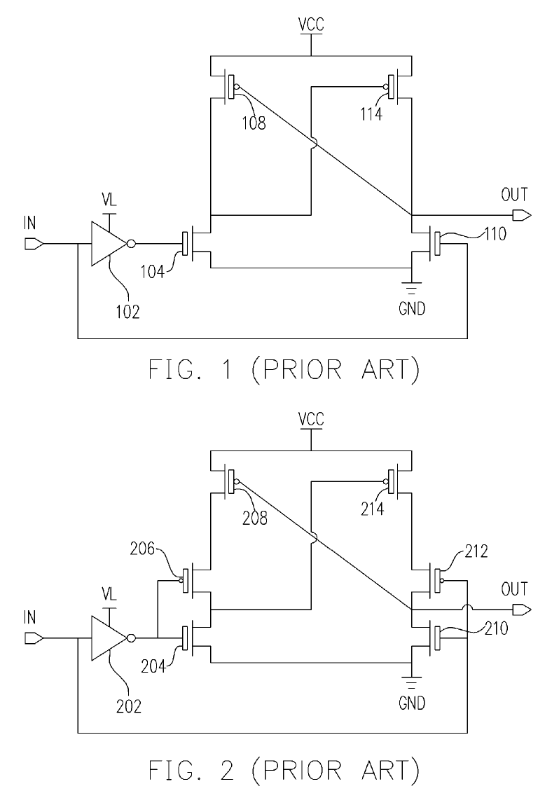

FIG. 3 is a schematic drawing of a level shifter circuit with a wide operating voltage range according to an embodiment of the present invention.

FIG. 4 is a schematic drawing of a level shifter circuit with a wide operating voltage range according to another embodiment of the present invention.

### DESCRIPTION OF THE EMBODIMENTS

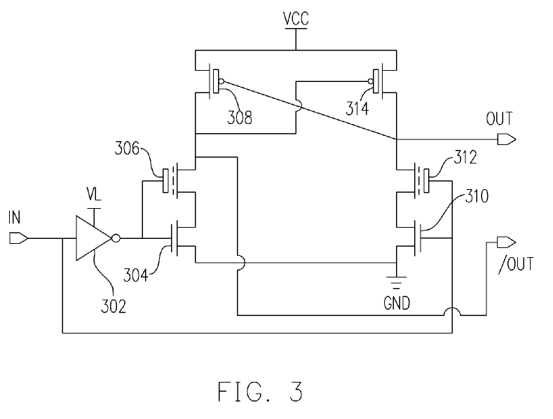

FIG. 3 is a schematic drawing of a level shifter circuit with a wide operating voltage range according to an embodiment of the present invention. Referring to FIG. 3, the level shifter circuit includes an inverter 302, a first transistor 304, a second transistor 306, a third transistor 308, a fourth transistor 310, a fifth transistor 312 and a sixth transistor 314. Wherein, the third transistor 308 and the sixth transistor 314 can be P-type transistors, while the first transistor 304, the second transistor 306, the fourth transistor 310 and the fifth transistor 312 can be N-type transistors. The second transistor 306 and the fifth transistor 312 have low threshold voltages and high breakdown voltages, while the first transistor 304 and the fourth transistor 310 have low threshold voltages. It is noted that the present invention is not limited to the aforementioned transistors, anyone skilled in the art should be able to modify the specifications of the transistors shown in FIG. 3 to meet a practical need, which is still without departing from the scope or spirit of the invention.

An input terminal of the inverter 302 receives an operating voltage VL, another input terminal thereof receives an input signal IN to which the gate of the fourth transistor 310 and the gate of the fifth transistor 312 are connected, while the output terminal of the inverter is electrically coupled to the gate of the first transistor 304 and the gate of the second transistor 306. One source/drain of the second transistor 306 is electrically coupled to one source/drain of the third transistor 308 and the gate of the sixth transistor 314, from the node connected between the second transistor 306 and the third transistor 308, there outputs an inverted output signal/OUT, and another source/drain of the second transistor 306 is electrically coupled to one source/drain of the first transistor 304. Another source/drain of the first transistor 304 is electrically coupled to the ground GND. Another source/drain of the third transistor 308 is electrically coupled to a power supply VCC and one source/drain of the sixth transistor 314. Another source/drain of the sixth transistor 314 is electrically coupled to the gate of the third transistor 308 and one source/drain of the fifth transistor 312, and from connected between the node of the fifth transistor 312 and the sixth transistor 314, there outputs an output signal OUT. Another source/drain of the fifth transistor 312 is electrically coupled to one source/drain of the fourth transistor 310. Another source/drain of the fourth transistor 310 is electrically coupled to the ground GND.

The aforementioned second transistor 306 and the fifth transistor 312 can be transistors with low threshold voltages and high breakdown voltages (the threshold voltage thereof is less than 0.5V) or transistors with negative threshold voltages and high breakdown voltages (or referred as depletion mode transistors), for example, native MOSFETs (metal oxide semiconductor field effect transistors) with high breakdown voltages (the threshold voltage thereof is between 0.1V˜0.2V); the first transistor 304 and the fourth transistor 310 can be thin-oxide MOSFETs with an absolute value of the threshold voltage less than 0.5V. In addition, the power supply serves as a power source for the output signal OUT and the inverted output signal/OUT so as to provide two signal levels, a lower level (i.e. the GND level as an output) and a high level (i.e. the level of the power supply VCC as an output). On the other hand, the operating voltage VL serves as a power source for the inverted input signal so as to provide two signal levels, a lower level (i.e. the GND level as an input) and a high level (i.e. the level of the operating voltage VL as an input).

Referring to FIG. 3 again, since the second transistor 306 and the fifth transistor 312 have low threshold voltages and high breakdown voltages and the first transistor 304 and the fourth transistor 310 have low threshold voltages, thus, as the operating voltage VL of the inverter 302 is less than 1V, the output of the inverter still attains the required threshold voltage of the first transistor 304 and the second transistor 306 or the fourth transistor 310 and the fifth transistor 312, which permits the level shifter circuit to normally work. Further, as the second transistor 306 and the fifth transistor 312 feature with their high breakdown voltages , the second transistor 306 can bear the most part of a voltage across between the node connected between the second transistor 306 and the third transistor 308, and another source/drain of the first transistor 304, which is electrically coupled to the ground GND, while the first transistor 304 bears the less part of the voltage when the first transistor 304 and the second transistor 306 are turned off and the power supply VCC presents at the inverted output signal/OUT as a high level. The first transistor 304 is thus protected by the second transistor 306 because of less sharing the power supply VCC stress.

Similarly, as the fourth transistor 310 and the fifth transistor 312 are turned off and the power supply VCC presents at the output signal OUT as a high level, the fifth transistor 312 can bear the most part of a voltage across between the node connected between the fifth transistor 312 and the sixth transistor 314, and the ground GND. In this way, the fourth transistor 310 is protected from being damaged by an excessive voltage beyond its breakdown voltage.

Continuing to FIG. 3, as the input signal IN is at the high level, the fourth transistor 310 and the fifth transistor 312 receive the input signal IN and accordingly are turned on. Meanwhile, the inverter 302 outputs a low level voltage and the first transistor 304 and the second transistor 306 are accordingly turned off. Since the fourth transistor 310 and the fifth transistor 312 are turned on, therefore, the node connected between the fifth transistor 312 and the sixth transistor 312 is at the ground level GND, which means the output signal OUT of the level shifter circuit is a low level, the third transistor 308 is turned on in response to the low level and the node connected between the second transistor 306 and the third transistor 308 is at the level of the power supply VCC, i.e. the inverted output signal/OUT is a high level.

As the input signal IN is the low level, the input signal IN is output to the gates of the first transistor 304 and the second transistor 306 through the inverter 302, which turns on the first transistor 304 and the second transistor 306. Meanwhile, the input signal IN received by the gates of the fourth transistor 310 and the fifth transistor 312 is a low level, which turns off the fourth transistor 310 and the fifth transistor 312. At the point, the node connected between the second transistor 306 and the third transistor 308 is at the grounding voltage GND and the sixth transistor 314 accordingly is turned on. Therefore, the output signal OUT of the level shifter circuit is the level of the power supply VCC, i.e. a high level. Since the fourth transistor 310 and the fifth transistor 312 are turned off, which in turn turns off the transistor 308 turn off, thus, the inverted output signal/OUT is a low level.

In addition, the first transistor 304 and the second transistor 306 in FIG. 3 receive the inverted input signal IN by the inverter 302, while the fourth transistor 310 and the fifth transistor 312 directly receive the input signal IN. Therefore, as the first transistor 304 and the second transistor 306 are turned on, the fourth transistor 310 and the fifth transistor 312 are turned off, while the first transistor 304 and the second transistor 306 are turned off, the fourth transistor 310 and the fifth transistor 312 are turned on. As a result, if the input signal keeps un-switched, no current would flow into the gate of the transistor in off-state, and no extra standby current is needed to keep the transistor in on-state either.

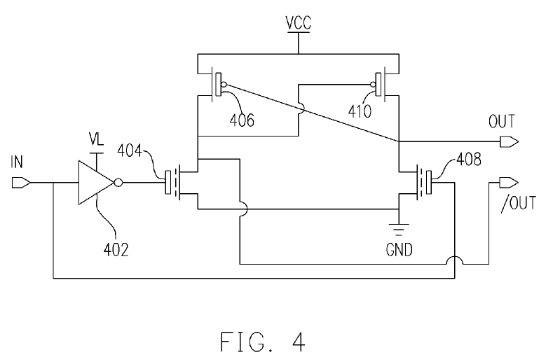

FIG. 4 is a schematic drawing of a level shifter circuit with wide operating voltage range according to another embodiment of the present invention. Referring to FIG. 4, the level shifter circuit includes an inverter 402, a first transistor 404, a second transistor 406, a third transistor 408 and a fourth transistor 410. Wherein, the electrical characteristics of the first transistor 404 and the third transistor 408 is opposite to those of the second transistor 406 and the fourth transistor 410, and the first transistor 404 and the third transistor 408 are transistors with low threshold voltage and high breakdown voltages. It is noted that the present invention is not limited to the aforementioned transistors, anyone skilled in the art should be able to modify the specifications of the transistors in FIG. 4 to meet a practical need, which doesn't still without depart from the scope or spirit of the invention.

An input terminal of the inverter 402 receives an operating voltage VL, another input terminal thereof received an input signal IN and is electrically coupled to the gate of the third transistor 408. One source/drain of the first transistor 404 is electrically coupled to the ground GND, while the gate thereof receives the output from the inverter 402. One source/drain of the second transistor 406 is electrically coupled to another source/drain of the first transistor 404 and from the node connected between the first transistor 404 and the second transistor 406, there outputs an inverted output signal/OUT. Another source/drain of the second transistor 406 is electrically coupled to the power supply VCC. One source/drain of the third transistor 408 is electrically coupled to the ground GND, and the gate thereof receives the input signal IN. One source/drain of the fourth transistor 410 is electrically coupled to another source/drain of the third transistor 408, and from the node connected between the third transistor 408 and the fourth transistor 410, there outputs an output signal OUT. The gate of the fourth transistor 410 is electrically coupled to the node connected between the first transistor 404 and the second transistor 406, while another source/drain of the fourth transistor 410 is electrically coupled to the power supply VCC.

The above-described first transistor 404 and the third transistor 408 have low threshold voltages and high breakdown voltages or transistors with negative threshold voltage and high breakdown voltage, for example, native MOSFETs (metal oxide semiconductor field effect transistors) with high breakdown voltage. In addition, the functions of the power supply VCC and the operating voltage VL are the same as those shown in FIG. 3 and their descriptions are omitted herein for simplicity.

Referring to FIG. 4 again, since the first transistor 404 and the third transistor 408 have high breakdown voltages, thus, as the inverted output signal/OUT is a high level (i.e. the level of the power supply VCC), the first transistor 404 itself can bear the voltage across the inverted output signal/OUT and the ground GND without being damaged. Similarly, as the output signal OUT is a high level (i.e. the level of the power supply VCC), the third transistor 408 itself can bear the voltage across the output signal OUT and the ground GND without being damaged.

Continuing to FIG. 4, as the input signal IN takes the high level, the third transistor 408 is turned on, which makes the output signal OUT take the level of the grounding voltage GND (i.e. the low level) and the second transistor 406 is accordingly turned on, causing the inverted output signal/OUT to be the level of the power supply VCC (i.e. the high level). At the point, the first transistor 404 receives the inverted input signal IN by the inverter 402 and accordingly is off.

As the input signal takes the low level, the first transistor 404 receives the inverted input signal by the inverter 402 and accordingly is turned on, which makes the inverted output signal/OUT receive the level of the ground voltage GND (i.e. the low level) and further accordingly turns on the fourth transistor 410. At the point, the output signal OUT is the level of the power supply VCC (i.e. the high level). Meanwhile, since the third transistor 404 receives the input signal with low level, the transistor 404 is turned off.

In summary, since the present invention adopts transistors with low threshold voltage and high breakdown voltage, and the absolute values of the threshold voltages of the adopted transistors are less than 0.5V, thus, as the operating voltage of the inverter is less than 1V but higher than the threshold voltages of the transistors with low threshold voltage, the level shifter circuit still functions normally. That is to say, the level shifter circuit with wide operating voltage range is very suitable for the circuit applications with a power supply voltage less than 1V. Moreover, no complex electrical design is required for the level shifter circuit to achieve the same performance and the responsive speed as a conventional circuit does.

It will be apparent to those skilled in the art that various modifications and variations can be made to the structure of the present invention without departing from the scope or spirit of the invention. In view of the foregoing, it is intended that the specification and examples to be considered as exemplary only, with a true scope and spirit of the invention being indicated by the following claims and their equivalents.

What is claimed is:

1. A level shifter circuit with a wide operating voltage range, comprising:
an inverter, receiving an input signal;
a first transistor, comprising one source/drain electrically coupled to the ground, and the gate electrically coupled to an output from the inverter;
a second transistor with a low threshold voltage and a high breakdown voltage, comprising one source/drain and the gate, which are electrically coupled to another source/drain of the first transistor and the gate of the first transistor, respectively;
a third transistor, comprising one source/drain transistor electrically coupled to another source/drain of the second transistor, while another source/drain of the third transistor is electrically coupled to a power supply;
a fourth transistor, comprising one source/drain electrically coupled to the ground, and the gate thereof electrically coupled to the input signal;
a fifth transistor with the low threshold voltage and the high breakdown voltage, comprising one source/drain and the gate electrically coupled to another source/drain of the fourth transistor and the gate of the fourth transistor, respectively, while another source/drain of the fifth transistor is electrically coupled to the gate of the third transistor; and
a sixth transistor, comprising one source/drain and the gate thereof electrically coupled to the another source/drains of the fifth transistor and the another source/drain of the second transistor, respectively, while another source/drain of the sixth transistor is electrically coupled to the power supply;
wherein the third transistor and the sixth transistor are doped with a first type impurity while the first transistor, the second transistor, the fourth transistor and the fifth transistor are doped with a second type impurity.

2. The level shifter circuit of claim 1, wherein the second transistor and the fifth transistor are native MOSFETs with high breakdown voltages.

3. The level shifter circuit of claim 1, wherein the second transistor and the fifth transistor have negative threshold voltages and high breakdown voltages.

4. The level shifter circuit of claim 1, wherein the second type impurity is N-type impurity while the first type impurity is P-type impurity.

5. The level shifter circuit of claim 1, wherein another source/drain of the fifth transistor is electrically coupled to an output terminal of the level shifter circuit.

6. The level shifter circuit of claim 1, wherein absolute values of threshold voltages of the first transistor and the fourth transistor are less than 0.5V.

7. A level shifter circuit with a wide operating voltage range, comprising:
an inverter, receiving an input signal;
a first transistor with a low threshold voltage and a high breakdown voltage, comprising one source/drain electrically coupled to the ground, and the gate electrically coupled to an output from the inverter;
a second transistor, comprising one source/drain electrically coupled to another source/drain of the first transistor, and another source/drain of the second transistor electrically coupled to a power supply;
a third transistor with the low threshold voltage and the high breakdown voltage, comprising one source/drain electrically coupled to the ground, and the gate electrically coupled to an input signal;
a fourth transistor, comprising one source/drain and the gate electrically coupled to another source/drains of the third transistor and the first transistor, respectively, and another source/drains of the fourth transistor electrically coupled to the power supply,
wherein the second transistor and the fourth transistor are doped with a first type impurity while the first transistor and the third transistor are doped with a second type impurity.

8. The level shifter circuit of claim 7, wherein the first transistor and the third transistor are native MOSFETs with high breakdown voltages.

9. The level shifter circuit of claim 7, wherein the first transistor and the third transistor are transistors with a negative threshold voltage and the high breakdown voltage.

10. The level shifter circuit of claim 7, wherein the second type impurity is N-type impurity while the first type impurity is P-type impurity.

11. The level shifter circuit of claim 10, wherein another source/drain of the third transistor is electrically coupled to the output terminal of the level shifter circuit.
